(19) United States
(12) Patent Application Publication
(10) Pub. No.: US 2024/0274492 A1
(43) Pub. Date: Aug. 15, 2024

(54) TEMPERATURE ADJUSTMENT DEVICE

(71) Applicants: KELK Ltd., Hiratsuka-shi (JP); TOKYO SEIMITSU CO., LTD., Hachioji-shi (JP)

(72) Inventors: Atsushi Kobayashi, Hiratsuka-shi (JP); Wataru Omuro, Hiratsuka-shi (JP); Takashi Motoyama, Hachioji-shi (JP); Takenori Takahashi, Hachioji-shi (JP); Shuhei Nishikawa, Hachioji-shi (JP)

(73) Assignees: KELK Ltd., Hiratsuka-shi (JP); TOKYO SEIMITSU CO., LTD., Hachioji-shi (JP)

(21) Appl. No.: 18/432,134

(22) Filed: Feb. 5, 2024

(30) Foreign Application Priority Data
Feb. 10, 2023 (JP) 2023-019208

(51) Int. Cl. H01L 23/367; H01L 23/38

(52) U.S. Cl. CPC H01L 23/3675; H01L 23/38

(57) ABSTRACT

A temperature adjustment device includes: a placement portion having a placement surface on which an object to be controlled temperature thereof is placed; a bottom portion facing the placement portion; a first support portion sandwiched between the placement portion and the bottom portion and supporting a center portion of the placement portion; a heat source portion disposed between the placement portion and the bottom portion and is allowed to heat and cool the object via the placement portion; a heat radiation portion disposed between the heat source portion and the bottom portion and exchanging heat with the heat source portion; and a second support portion disposed between the placement portion and the bottom portion and disposed close to the axis, wherein the second support portion supports an end portion of the heat radiation portion so as to separate the heat radiation portion from the bottom portion.

### TECHNICAL FIELD

The present invention relates to a temperature adjustment device. Priority is claimed on Japanese Patent Application No. 2023-19208, filed on Feb. 10, 2023, the content of which is incorporated herein by reference.

### BACKGROUND ART

In a semiconductor manufacturing apparatus, a temperature adjustment device which adjusts the temperature of a wafer is used.

For example, Japanese Unexamined Patent Application, First Publication No. 2002-185051 discloses a circular cooling plate which cools a wafer as an example of the temperature adjustment device. This circular cooling plate includes a thermo module formed by arranging a plurality of Peltier elements between a pair of heat transfer plates.

In such a temperature adjustment device, a Peltier module is disposed between a top plate and a bottom plate as a heat source portion and the Peltier module and the top plate are stacked on the bottom plate. The bottom plate has a mounting surface which is formed on the lower surface so that other devices are mounted thereon and the top plate has a placement surface which is formed on the upper surface so that a temperature control object to be controlled temperature such as a wafer is placed thereon.

### SUMMARY OF INVENTION

### Technical Problem

Incidentally, the top plate and the bottom plate expand and contract due to temperature changes during temperature control. Usually, each member constituting the temperature adjustment device has different expansion coefficients and temperature conditions. For this reason, there are differences in expansion and contraction amount between members. In the above-described conventional temperature adjustment device, since the top plate is stacked on the bottom plate, there is concern that the placement surface of the top plate may be deformed to be inclined with respect to the mounting surface of the bottom plate due to the difference in expansion and contraction amount.

Particularly in the semiconductor industry, the placement surface is required to have a high parallelism of, for example, 0.015 mm. However, in the above-described conventional technique, it has been considered difficult to maintain parallelism as high as about 0.015 mm regardless of temperature changes.

The present invention has been made to solve the above-described problems and an object thereof is to provide a temperature adjustment device capable of improving the parallelism of a placement surface.

### Solution to Problem

In order to solve the above-described problems, a temperature adjustment device according to the present invention includes: a placement portion having a placement surface on which an object to be controlled temperature thereof is placed; a bottom portion sharing an axis extending in a first direction with the placement portion and facing the placement portion in the first direction; a first support portion which is sandwiched between the placement portion and the bottom portion from both sides in the first direction and supporting a center portion of the placement portion; a heat source portion which is disposed between the placement portion and the bottom portion in the first direction and is allowed to heat and cool the object via the placement portion; a heat radiation portion which is disposed between the heat source portion and the bottom portion in the first direction and exchanging heat with the heat source portion; and a second support portion which is disposed between the placement portion and the bottom portion and which is disposed close to the axis passing through the center portion, wherein the second support portion supports an end portion of the heat radiation portion in a second direction intersecting the axis so as to separate the heat radiation portion from the bottom portion in the first direction.

### Advantageous Effects of Invention

According to the present invention, it is possible to improve the parallelism of the placement surface.

### BRIEF DESCRIPTION OF DRAWINGS

FIG. 1 is a plan view showing a temperature adjustment device according to an embodiment of the present invention.

FIG. 2 is a cross-sectional view taken along a line II-II of FIG. 1.

FIG. 3 is an enlarged view showing an outer peripheral portion of a top plate of the temperature adjustment device according to the embodiment of the present invention.

FIG. 4 is a perspective view of an outside portion according to the embodiment of the present invention.

FIG. 5 is a cross-sectional view of a temperature adjustment device according to a first modified example of the present invention.

FIG. 6 is a cross-sectional view of a temperature adjustment device according to a second modified example of the present invention.

FIG. 7 is a cross-sectional view of a temperature adjustment device according to a third modified example of the present invention.

FIG. 8 is an enlarged view showing an outer peripheral portion of a top plate of a temperature adjustment device according to a fourth modified example of the present invention.

### DESCRIPTION OF EMBODIMENTS

### Configuration of Temperature Adjustment Device

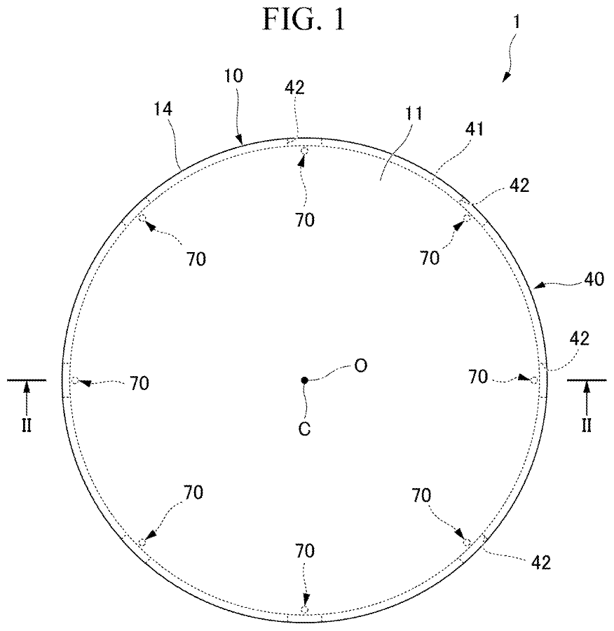

Hereinafter, a temperature adjustment device 1 according to an embodiment of the present invention will be described with reference to FIGS. 1 to 4. The temperature adjustment device 1 shown in FIG. 1 is installed in, for example, a semiconductor manufacturing apparatus. This temperature adjustment device 1 supports a semiconductor wafer A, which is subjected to a predetermined process such as a plasma process or an etching process in the semiconductor manufacturing apparatus, from below. The temperature adjustment device 1 adjusts the temperature of the semiconductor wafer A to a temperature suitable for a predetermined process.

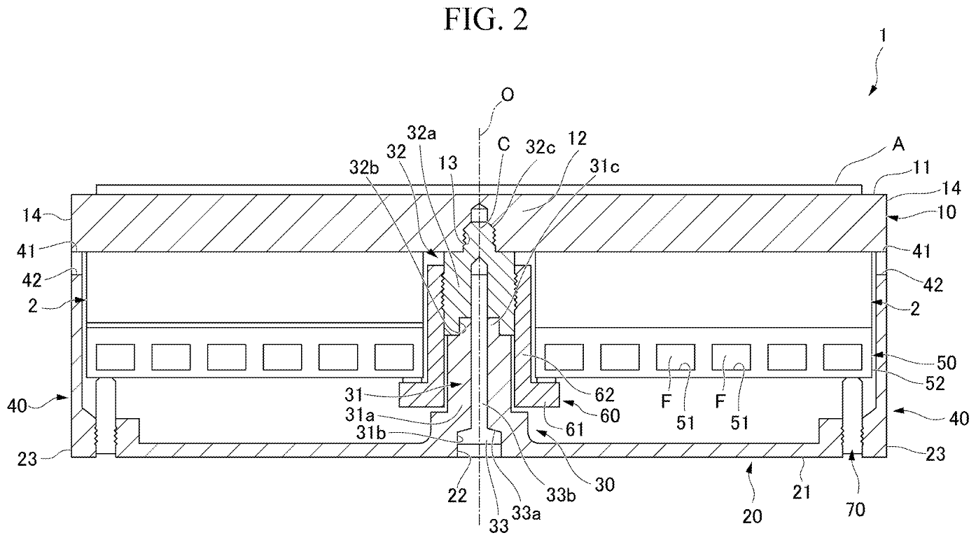

As shown in FIGS. 1 and 2, the temperature adjustment device 1 includes a top plate 10 (placement portion), a bottom plate 20 (bottom portion), a first support portion 30, an outside portion 40, a Peltier module 2 (heat source portion), a cooling plate 50 (heat radiation portion), and a second support portion 60.

### Top Plate

The top plate 10 has a placement surface 11 on which a temperature control object (the semiconductor wafer A in the case of this embodiment) is placed. The top plate 10 is a disk-shaped member made of a heat transfer material and having a uniform thickness. Hereinafter, the center axis O of the top plate 10 is simply referred to an axis O. This axis O passes through a center portion 12 of the top plate 10 and extends in a straight line in the plate thickness direction of the top plate 10. This center portion 12 is a predetermined area close to the center C including the center C of the top plate 10 when viewed from the plate thickness direction. In this embodiment, the axis O passes through the center C in the center portion 12. Furthermore, the axis O may extend through a position slightly shifted from the center C of the center portion 12.

Further, the radial direction of the axis O is simply referred to as the “radial direction” and the circumferential direction of the axis O is simply referred to as the “circumferential direction”. The radial direction intersects (is perpendicular to) the direction of the axis O. The direction of the axis O is an example of a first direction and the radial direction is an example of a second direction.

Further, an example will be described below in which the top plate 10 is disposed along the horizontal plane and the axis O of the top plate 10 extends in the vertical up and down direction.

Further, a fastening hole 13 is formed on the lower surface of the center portion 12 of the top plate 10. The above-described top plate 10 expands and contracts under the influence of the heat of the Peltier module 2 which will be described later and is disposed below. For example, the top plate 10 expands in the radial direction at a high temperature and the top plate 10 contracts in the radial direction at a low temperature.

### Bottom Plate

The bottom plate 20 is disposed at a position facing the top plate 10 in the direction of the axis O. The bottom plate 20 is formed in a disk shape of which the center axis coincides with the axis O. The bottom plate 20 is formed to have approximately the same diameter as the top plate 10.

The bottom plate 20 has a mounting surface 21 on the side opposite to the top plate 10 in the direction of the axis O. The mounting surface 21 extends in parallel to the placement surface 11. The bottom plate 20 is mounted on an apparatus body or the like of a semiconductor manufacturing apparatus using this mounting surface 21.

Further, an insertion passage hole 22 is formed in the bottom plate 20 to penetrate along the axis O.

### First Support Portion

The first support portion 30 is sandwiched between the top plate 10 and the bottom plate 20 from both sides in the direction of the axis O. The first support portion 30 supports the center portion 12 of the top plate 10. The first support portion 30 extends in one direction along the axis O. The first support portion 30 includes a first portion 31, a second portion 32, and a bolt 33. The first portion 31 and the second portion 32 are arranged side by side along the axis O. The first portion 31 is disposed close to the bottom plate 20 in the direction of the axis O and the second portion 32 is disposed close to the top plate 10 in the direction of the axis O.

In this embodiment, the first portion 31 is integrally formed with the bottom plate 20. The first portion 31 includes a base portion 31a, a concave portion 31b, and a convex portion 31c. The base portion 31a is a columnar member extending from the bottom plate 20 in the direction of the axis O. The concave portion 31b is formed at the end portion of the base portion 31a close to the bottom plate 20 in the direction of the axis O. The concave portion 31b communicates with the insertion passage hole 22 of the bottom plate 20. The convex portion 31c protrudes toward the second portion 32 from the end portion of the base portion 31a close to the top plate 10 in the direction of the axis O.

The second portion 32 includes a base portion 32a, a concave portion 32b, and a convex portion 32c. The base portion 32a is a columnar member extending in the direction of the axis O similar to the base portion 31a of the first portion 31. However, the base portion 32a of the second portion 32 is formed to have a slightly larger diameter than the base portion 31a of the first portion 31. The concave portion 32b is formed at the end of the base portion 32a portion close to the bottom plate 20 in the direction of the axis O. The convex portion 32c protrudes toward the top plate 10 from the end portion of the base portion 32a close to the top plate 10 in the direction of the axis O. The convex portion 32c is disposed inside the fastening hole 13 of the top plate 10. The top plate 10 is fixed to the first support portion 30 by fastening and fixing the convex portion 32c and the fastening hole 13.

The bolt 33 includes a threaded portion 33b and a head 33a. The bolt 33 is inserted from the concave portion 31b of the first portion 31 in the direction of the axis O. The threaded portion 33b extends into the base portion 32a of the second portion 32 through the first portion 31 so that the tip of the threaded portion 33b is fastened to the second portion 32. Further, the head 33a is completely accommodated inside the concave portion 31b of the first portion 31.

### Outside Portion

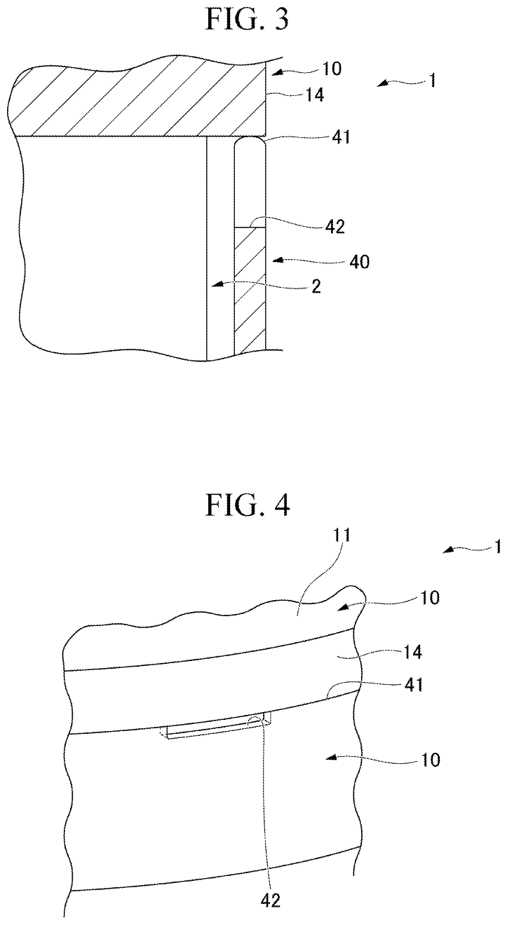

The outside portion 40 is provided in an outer peripheral portion 23 of the bottom plate 20 separated from the axis O in the radial direction. The outside portion 40 extends from the bottom plate 20 toward the top plate 10 in the direction of the axis O. The outside portion 40 supports the outer peripheral portion 14 of the top plate 10 separated from the axis O in the radial direction. In this embodiment, the outside portion 40 is an outer peripheral wall provided over the entire circumference of the outer peripheral portion 23 of the bottom plate 20. The internal structure of the temperature adjustment device 1 is shielded by the outside portion 40. Further, as shown in FIG. 3, a contact portion 41 of the outside portion 40 close to the top plate 10 in the direction of the axis O is formed to taper toward the top plate 10 in the direction of the axis O.

Further, as shown in FIG. 4, a groove portion 42 is formed in the contact portion 41. For example, a plurality of the groove portions 42 are formed at the same intervals in the circumferential direction.

The Peltier module 2 is disposed in an area surrounded by the above-described side portion 40.

### Peltier Module

The Peltier module 2 is disposed between the top plate 10 and the bottom plate 20 in the direction of the axis O. The Peltier module 2 can heat and cool the temperature control object via the top plate 10. The Peltier module 2 is disposed to surround the first support portion 30 from the outside in the radial direction.

### Cooling Plate

The cooling plate 50 is disposed between the Peltier module 2 and the bottom plate 20 in the direction of the axis O and exchanges heat with the Peltier module 2. The cooling plate 50 is formed in an annular plate shape which surrounds the first support portion 30 from the outside in the radial direction. A flow path 51 through which a refrigerant F flows is formed inside the cooling plate 50. The cooling plate 50 cools the Peltier module 2 by exchanging heat between the Peltier module 2 and the refrigerant F flowing through the flow path 51. The second support portion 60 which supports the cooling plate 50 from below is disposed on the inner peripheral side of the cooling plate 50.

### Second Support Portion

The second support portion 60 is disposed between the top plate 10 and the bottom plate 20 in the direction of the axis O. The second support portion 60 is disposed close to the axis O in the radial direction. The second support portion 60 supports the end portion of the cooling plate 50 close to the center portion 12 and separates the cooling plate 50 from the bottom plate 20 in the direction of the axis O.

In this embodiment, the second support portion 60 includes a main body portion 61 supporting the cooling plate 50 disposed with being separated from the first support portion 30 in the radial direction and a connection portion 62 extending from the main body portion 61 toward the top plate 10 in the direction of the axis O and is connected to the first support portion 30 at the end portion of the connection portion close to the top plate 10 in the direction of the axis O. More specifically, the main body portion 61 is formed in an annular shape which surrounds the first support portion 30 from the outside in the radial direction and the connection portion 62 is formed in a cylindrical shape which extends from the inner peripheral end of the main body portion 61 toward the top plate 10 in the direction of the axis O. The connection portion 62 is fixed to the outer peripheral surface of the second portion 32 of the first support portion 30 at the inner peripheral surface by, for example, screwing.

Further, a third support portion 70 is disposed in the outer peripheral portion 23 of the bottom plate 20.

### Third Support Portion

The third support portion 70 is disposed between the top plate 10 and the bottom plate 20 in the direction of the axis O. The third support portion 70 supports an outer peripheral portion 52 of the cooling plate 50 separated from the axis O in the radial direction. The third support portion 70 of this embodiment is a bolt which extends from the bottom plate 20 in the direction of the axis O. The third support portion 70 is fixed to the bottom plate 20 by screwing the end portion of the third support portion 70 close to the bottom plate 20 in the direction of the axis O with the bottom plate 20. The cooling plate 50 is placed on the end portion of the third support portion 70 close to the top plate 10 in the direction of the axis O. A plurality of (for example, eight to twelve) third support portions 70 are formed side by side in the circumferential direction.

In this way, in the above-described temperature adjustment device 1, the cooling plate 50, the Peltier module 2, and the top plate 10 are stacked in order in the direction of the axis O. On the other hand, the cooling plate 50 and the bottom plate 20 are separated from each other in the direction of the axis O by the second support portion 60 and the third support portion 70.

### <Effect>

The temperature adjustment device 1 of the above-described embodiment can exhibit the following effects.

In this embodiment, the second support portion 60 is disposed close to the axis O in the radial direction, supports the end portion of the cooling plate 50 close to the axis O, so as to separate the cooling plate 50 from the bottom plate 20 from each other.

Accordingly, deformation of the cooling plate 50 due to the thermal expansion and contraction can be absorbed a space between the cooling plate 50 and the bottom plate 20. Thus, since the deformation of the cooling plate 50 is less likely to be transmitted to the top plate 10, it is possible to improve the parallelism of the placement surface 11 of the top plate 10.

Further, the top plate 10 is fixed only at the center portion 12 and can freely extend in the radial direction.

In this embodiment, the second support portion 60 includes the main body portion 61 supporting the cooling plate 50 with being separated from the first support portion 30 in the radial direction and the connection portion 62 extending toward the top plate 10 in the direction of the axis O and is connected to the first support portion 30 at the end portion of the connection portion close to the top plate 10 in the direction of the axis O.

Accordingly, the cooling plate 50 and the bottom plate 20 are thermally separated and the thermal expansion and contraction of the bottom plate 20 is suppressed. Accordingly, the deformation amount transmitted from the bottom plate 20 to the top plate 10 is reduced and the inclination of the top plate 10 is suppressed. Thus, the parallelism of the placement surface 11 of the top plate 10 is further improved.

In this embodiment, the temperature adjustment device 1 further includes the outside portion 40 which is disposed on the outer peripheral portion 23 of the bottom plate 20, extends from the bottom plate 20 toward the top plate 10 in the direction of the axis O, wherein the outside portion 40 supports the outer peripheral portion 14 of the top plate 10.

Accordingly, since the top plate 10 is also supported from the outer peripheral side, the safety is improved. Thus, since the inclination of the top plate 10 is suppressed, the parallelism of the placement surface 11 of the top plate 10 is further improved.

In this embodiment, the temperature adjustment device 1 further includes the third support portion 70 which is disposed between the top plate 10 and the bottom plate 20 in the direction of the axis O and supporting the outer peripheral portion 52 of the cooling plate 50.

Accordingly, since the cooling plate 50 is also supported from the outer peripheral side, the safety is improved.

In this embodiment, the contact portion 41 of the outside portion 40 close to the top plate 10 in the direction of the axis O is formed to taper toward the top plate 10 in the direction of the axis O.

Accordingly, since the contact area between the outside portion 40 and the top plate 10 is reduced, the expansion and contraction of the top plate 10 can be suppressed from being hindered by the outside portion 40. Thus, since the inclination of the placement surface 11 of the top plate 10 is suppressed, the parallelism of the placement surface 11 is improved.

Further, in this embodiment, the contact portion 41 is provided with the groove portion 42.

Accordingly, since the contact area between the side portion 40 and the top plate 10 can be further reduced, the expansion and contraction of the top plate 10 can be further suppressed from being hindered by the side portion 40. Thus, since the inclination of the placement surface 11 of the top plate 10 is suppressed, the parallelism of the placement surface 11 is further improved.

Although the embodiment of the present invention has been described with reference to the drawings, the specific configuration is not limited to this embodiment and may include design changes without departing from the gist of the present invention.

In the above-described embodiment, although it has been described that the temperature adjustment device 1 is installed in the semiconductor manufacturing apparatus, the present invention is not limited thereto and the temperature adjustment device may be installed in a semiconductor inspection device.

Further, in the above-described embodiment, an example has been described in which the temperature control object is the semiconductor wafer A, but the present invention is not limited thereto.

Further, in the above-described embodiment, an example has been described in which the placement portion is a disk-shaped member (top plate 10) having a uniform thickness, but the present invention is not limited thereto. The placement portion may have a flat placement surface 11 and have a thickness that can be heated and cooled by a heat source portion. For example, the placement portion may have a rectangular plate shape or a block shape.

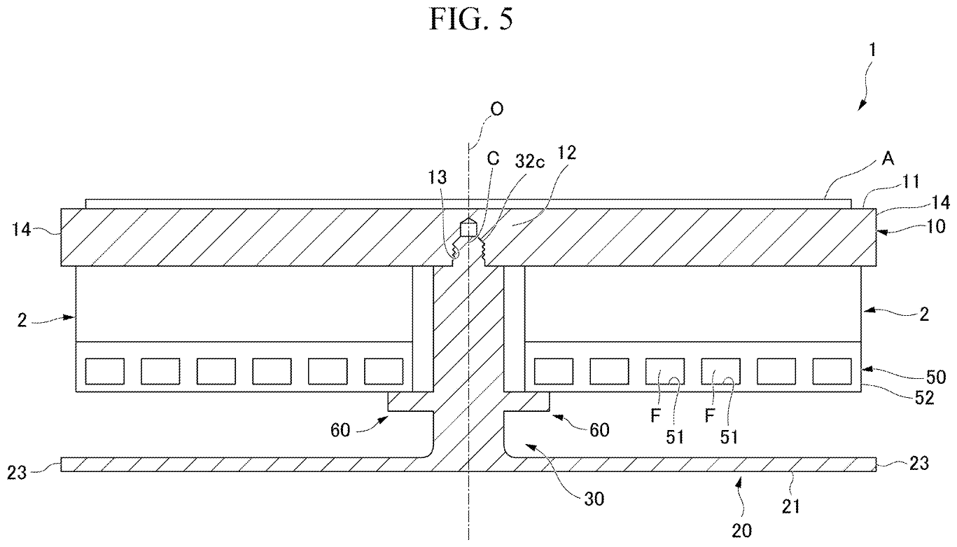

Further, for example, as shown in FIG. 5, the temperature adjustment device 1 may not include the outside portion 40 which supports the outer peripheral portion 14 of the top plate 10. Further, the first support portion 30 may not be divided into the first portion 31 and the second portion 32, but may be a single pillar member. In the above-described embodiment, an example has been described in which the second support portion 60 is formed in an L shape including the main body portion 61 and the connection portion 62 in the cross-sectional view. However, the present invention is not limited thereto, as shown in FIG. 5, the second support portion 60 may be formed in a flange shape which protrudes outward in the radial direction from the first support portion 30, and the cooling plate 50 may be placed on the second support portion 60 having a flange shape.

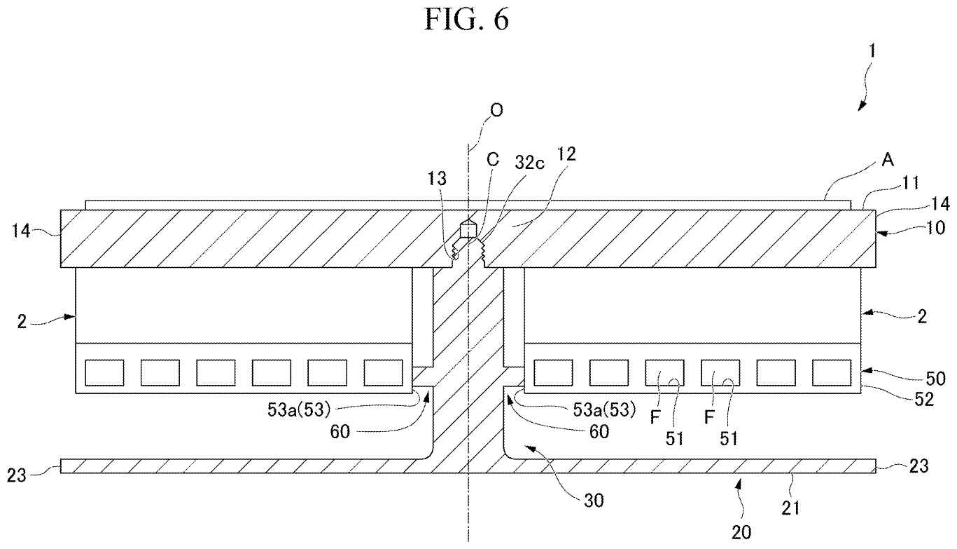

Further, for example, as shown in FIG. 6, the second support portion 60 may be protruded outward in the radial direction from the first support portion 30 to have a flange shape. In this modified example, the second support portion 60 is fixed to the inner peripheral portion 53 of the cooling plate 50 close to the axis O in the radial direction. More specifically, the outer radial end portion of the second support portion 60 is fixed to an inner surface 53a which faces the axis O in the radial direction of the inner peripheral portion 53 by, for example, fastening or welding. In this case, since the length of the temperature adjustment device 1 in the direction of the axis O is shortened, the temperature adjustment device 1 can be manufactured even more compactly.

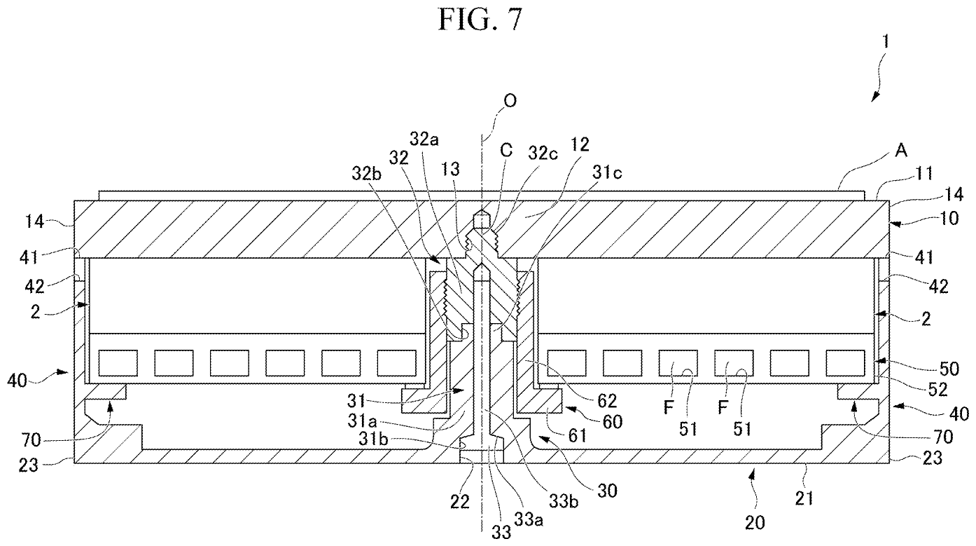

Further, in the above-described embodiment, the third support portion 70 is a bolt which extends from the bottom plate 20 in the direction of the axis O, but the present invention is not limited thereto. For example, as shown in FIG. 7, the third support portion 70 may be a plate-shaped member that extends inward in the radial direction from the inner peripheral surface of the outside portion 40. Further, the temperature adjustment device 1 may not include the third support portion 70. However, the case in which the temperature adjustment device 1 includes the third support portion 70 is advantageous in that the Peltier module 2 or the cooling plate 50 can be stably supported.

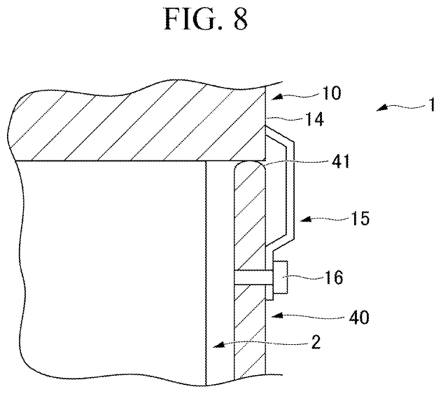

Further, for example, as shown in FIG. 8, the outer peripheral portion 14 of the top plate 10 may be provided with a fixed portion 15 which extends toward the bottom plate 20 in the direction of the axis O. The fixed portion 15 is disposed to overlap the outside portion 40 from the outside in the radial direction and is fixed by a screw 16 in the radial direction. Accordingly, since the top plate 10 and the outside portion 40 are connected, it is possible to improve the strength of the temperature adjustment device 1.

### REFERENCE SIGNS LIST

1 Temperature adjustment device
2 Peltier module (heat source portion)
10 Top plate (placement portion)
11 Placement surface
12 Center portion
13 Fastening hole
14 Outer peripheral portion
15 Fixed portion
16 Screw
20 Bottom plate (bottom portion)
21 Mounting surface
22 Insertion passage hole
23 Outer peripheral portion
30 First support portion
31 First portion
31a Base portion
31b Concave portion
31c Convex portion
32 Second portion
32a Base portion
32b Concave portion
32c Convex portion
33 Bolt
33a Head
33b Threaded portion
40 outside portion
41 Contact portion
42 Groove portion
50 Cooling plate (heat radiation portion)
51 Flow path
52 Outer peripheral portion
53 Inner peripheral portion
53a Inner surface
60 Second support portion
61 Main body portion
62 Connection portion
70 Third support portion
A Semiconductor wafer
C Center
F Refrigerant
O Axis

What is claimed is:

1. A temperature adjustment device comprising:
a placement portion having a placement surface on which an object to be controlled temperature thereof is placed;
a bottom portion sharing an axis extending in a first direction with the placement portion and facing the placement portion in the first direction;
a first support portion which is sandwiched between the placement portion and the bottom portion from both sides in the first direction and supporting a center portion of the placement portion;
a heat source portion which is disposed between the placement portion and the bottom portion in the first direction and is allowed to heat and cool the object via the placement portion;
a heat radiation portion which is disposed between the heat source portion and the bottom portion in the first direction and exchanging heat with the heat source portion; and
a second support portion which is disposed between the placement portion and the bottom portion and which is disposed close to the axis passing through the center portion, wherein the second support portion supports an end portion of the heat radiation portion in a second direction intersecting the axis so as to separate the heat radiation portion from the bottom portion in the first direction.

2. The temperature adjustment device according to claim 1,
wherein the second support portion includes:
a main body portion supporting the heat radiation portion with being separated from the first support portion in the second direction; and
a connection portion extending from the main body portion toward the placement portion in the first direction and is connected to the first support portion at an end portion of the connection portion close to the placement portion in the first direction.

3. The temperature adjustment device according to claim 1, further comprising:
an outside portion which is disposed on an outer peripheral portion of the bottom portion to be separated from the axis in the second direction and extending from the bottom portion toward the placement portion in the first direction, wherein the outside portion supports an outer peripheral portion of the placement portion separated from the axis in the second direction.

4. The temperature adjustment device according to claim 1, further comprising:
a third support portion which is disposed between the placement portion and the bottom portion in the first direction and supporting an outer peripheral portion of the heat radiation portion separated from the axis in the second direction.

5. The temperature adjustment device according to claim 1,
wherein the second support portion is protruded from the first support portion in the second direction and is fixed to an inner surface of the heat radiation portion close to the axis in the second direction.
